(19) United States
(12) Patent Application Publication
(10) Pub. No.: US 2020/0358423 A1
(43) Pub. Date: Nov. 12, 2020

(54) PIEZOELECTRIC FILM CAVITY STRUCTURE FOR A BULK ACOUSTIC WAVE (BAW) RESONATOR AND METHOD THEREFOR

(71) Applicant: OEpic SEMICONDUCTORS, INC, Sunnyvale, CA (US)

(72) Inventors: Yi-Ching Pao, Sunnyvale, CA (US); Majid Riaziat, Sunnyvale, CA (US); James Pao, Sunnyvale, CA (US)

(21) Appl. No.: 16/867,133

(22) Filed: May 5, 2020

Related U.S. Application Data
(60) Provisional application No. 62/845,794, filed on May 9, 2019.

(51) Int. Cl. H03H 9/17; H01L 41/313; H01L 41/332; H03H 9/05

(52) U.S. Cl. CPC H03H 9/173; H01L 41/313; H03H 2003/021; H03H 9/0523; H03H 9/176; H01L 41/332

(57) ABSTRACT

A method for forming a Bulk Acoustic Wave (BAW) structure comprises forming a piezoelectric material on a first substrate; applying a first metal layer on a top surface of the piezoelectric material; forming a metal pattern on a second substrate, the metal pattern forming a cavity pattern between raised areas of the metal pattern; attaching the first metal layer to a top area of the metal pattern forming a plurality of cavity areas; removing the first substrate; and applying a second metal layer on a bottom surface of the piezoelectric material.

### RELATED APPLICATIONS

This patent application is related to U.S. Provisional Application No. 62/845,794 filed May 9, 2019, entitled “NOVEL PIEZOELECTRIC FILM CAVITY STRUCTURE FOR BAW RESONATORS” in the names of Yi-Ching Pao, Majid Riaziat and James Pao, and which is incorporated herein by reference in its entirety. The present patent application claims the benefit under 35 U.S.C § 119(e).

### TECHNICAL FIELD

The present invention generally relates to Bulk Acoustic Wave (BAW) structures and, more particularly to, a cavity formation and manufacturing process that simplifies the cavity formation underneath the Film Bulk Acoustic Resonator (FBAR) structure, and eliminates the need of substrate trench etching, subsequent planarization processes, micro-via formation, sacrificial layer and planarized support layer deposition and subsequent removal, and large area planar wafer bonding process.

### BACKGROUND

Piezoelectric thin film Bulk Acoustic Wave (BAW) structures are typically used to manufacture Bulk Acoustic Resonators (BAR) for filter and duplexer in microwave applications. Two basic BAW structures have developed over the years, namely FBAR (Film BAR) and SMBAR (Solidly Mounted BAR). FBAR and SMBAR both have their own pros and cons, but overall, the FBAR has been gaining more and more market share in today's microwave communication applications. The FBAR structure is a cavity-based structure wherein the manufacturing of it has been mainly based on etching a trench on the silicon substrate, combined with surface planarization with Chemical Mechanical Polishing (CMP).

U.S. Pat. No. 6,060,818 discloses a prior art method of forming a FBAR structure. In this patent, as may be seen in FIGS. 1A-1E, the FBAR structure may be formed by etching a cavity 10 into a silicon substrate 12 as shown in FIG. 1A. A thin layer of thermal oxide 14 may be applied to prevent chemical diffusion. Such diffusion may convert the silicon to a conductor, which would interfere with the electrical operation of the final device. A layer of phosphor-silica-glass (PSG) 16 may be deposited filling the cavity 10 as shown in FIG. 1B. The surface of the PSG layer 16 is first planarized by polishing with a slurry to remove the portion of the PSG layer 16 outside of the cavity 10 as shown in FIG. 1C. The remaining PSG layer 16 can then be polished using a more refined slurry. As shown in FIG. 1D, an FBAR 20 may then be formed. A bottom electrode 18 of the FBAR 20 may then be deposited. After the bottom electrode 18 has been deposited, a piezoelectric layer 22 of the FBAR 20 may be deposited. Finally, the top electrode 24 may deposited. As shown in FIG. 1E, the PSG layer 16 in the cavity 10 may be removed through via holes to form the underlying cavity 10. The above process is time consuming and complicated due to the multiple layers than need to be formed.

In recent years there were additional BAW resonator related development works toward using single crystal piezoelectric film with copper pillar, solder bump, perimeter structure, and micro-vias as disclosed in “RESONANCE CIRCUIT WITH A SINGLE CRYSTAL CAPACITOR DIELECTRIC MATERIAL”, U.S. Pat. No. 9,673,384 B2, issued on Jun. 6, 2017; “SINGLE CRYSTAL ACOUSTIC RESONATOR AND BULK ACOUSTIC WAVE FILTER”, U.S. Pat. No. 9,912,314132, issued on Mar. 6, 2018; “STRUCTURE AND METHOD OF MANUFACTURE FOR ACOUSTIC RESONATOR OR FILTER DEVICES USING IMPROVED FABRICATION CONDITIONS AND PERIMETER STRUCTURE MODIFICATIONS”, U.S. Pat. No. 10,110,190 B2, issued on Oct. 23, 2018; and “METHOD OF MANUFACTURE FOR SINGLE CRYSTAL ACOUSTIC RESONATOR DEVICES USING MICRO-VIAS”, U.S. Pat. No. 10,217,930 B1, issued on Feb. 26, 2019.

Even work directed towards piezoelectric film transfer from one substrate to another to form the preferred cavity structure has been done as disclosed in “PIEZOELECTRIC FILM TRANSFER FOR ACOUSTIC RESONATORS AND FILTERS”, US 2015/0033520 A1, published on Feb. 5, 2015 and “PIEZOELECTRIC ACOUSTIC RESONATOR MANUFACTURED WITH PIEZOELECTRIC THIN FILM TRANSFER PROCESS”, US 2018/0054176 A1, published on Feb. 22, 2018. The advantage of using single crystal piezoelectric thin film has not shown significant improvement in resonator performance compares to plasma sputtered poly crystalline thin film.

Referring to FIGS. 2-4, US 2018/0054176 A1 described a method of constructing an acoustic resonator through the use of simple thin film transfer for forming both SMR (Solidly Mount Resonator) (FIG. 3) and FBAR (Film Bulk Acoustic Resonator) (FIG. 4). The method comprises forming a piezoelectric material on a first substrate with a sacrificial layer and planarized support layer deposition (FIG. 2) and their subsequent removal. Through a wafer bonding process, the piezoelectric material is applied onto a second substrate on which the acoustic resonator is used as the base (FIG. 3-4). This prior art, in addition to the use of sacrificial and support layer deposition, may require subsequent cavity etching into the support layer or using a reflector structure to replace the cavity which may makes the approach complicated and difficult to fabricate. However, it does not disclose any possible path or detailed description of performing the wafer scale bonding over large wafers.

Therefore, it would be desirable to provide a device and method that overcome the above problems.

### SUMMARY

In accordance with one embodiment, a method for forming Bulk Acoustic Wave (BAW) structure is disclosed. The method comprises: forming a piezoelectric material on a first substrate; applying a first metal layer on a top surface of the piezoelectric material; forming a metal pattern on a second substrate, the metal pattern forming a cavity pattern between raised areas of the metal pattern; attaching the first metal layer to a top area of the metal pattern forming a plurality of cavity areas; removing the first substrate; and applying a second metal layer on a bottom surface of the piezoelectric material.

In accordance with one embodiment, a method for forming Bulk Acoustic Wave (BAW) structure is disclosed. The method comprises: forming a piezoelectric material on a first substrate; applying a first metal layer on a top surface of the piezoelectric material; forming a metal pattern on a second substrate, the metal pattern forming a cavity pattern between raised areas of the metal pattern; attaching the first metal layer to a top area of the metal pattern forming a plurality of cavity areas; removing the first substrate; applying a second metal layer on a bottom surface of the piezoelectric material; removing portions of the second metal layer and the piezoelectric material to form a plurality of BAW structures, each of the plurality of BAW structures having one of the plurality of cavity areas; and forming interconnects on at least one of the plurality of BAW structures.

In accordance with one embodiment, a method for forming Bulk Acoustic Wave (BAW) structure is disclosed. The method comprises: forming a piezoelectric material on a first substrate; applying a first metal layer on a top surface of the piezoelectric material; forming a metal pattern on a second substrate, the metal pattern forming a cavity pattern between raised areas of the metal pattern; etching into the first substrate in the cavity pattern deepening at least one of the plurality of cavity areas; attaching the first metal layer to a top area of the metal pattern forming a plurality of cavity areas; removing the first substrate; applying a second metal layer on a bottom surface of the piezoelectric material; removing portions of the second metal layer and the piezoelectric material to form a plurality of BAW structures, each of the plurality of BAW structures having one of the plurality of cavity areas; forming interconnects on at least one of the plurality of BAW structures; forming a plurality of mounting pillars on the first substrate; and flip chip mounting the first substrate with the plurality of mounting pillars on to a third substrate.

### BRIEF DESCRIPTION OF THE DRAWINGS

The present application is further detailed with respect to the following drawings. These figures are not intended to limit the scope of the present application but rather illustrate certain attributes thereof. The same reference numbers will be used throughout the drawings to refer to the same or like parts.

FIG. 1A-1E show cross-sectional views of a method for forming a prior art Bulk Acoustic Wave (BAW) device;

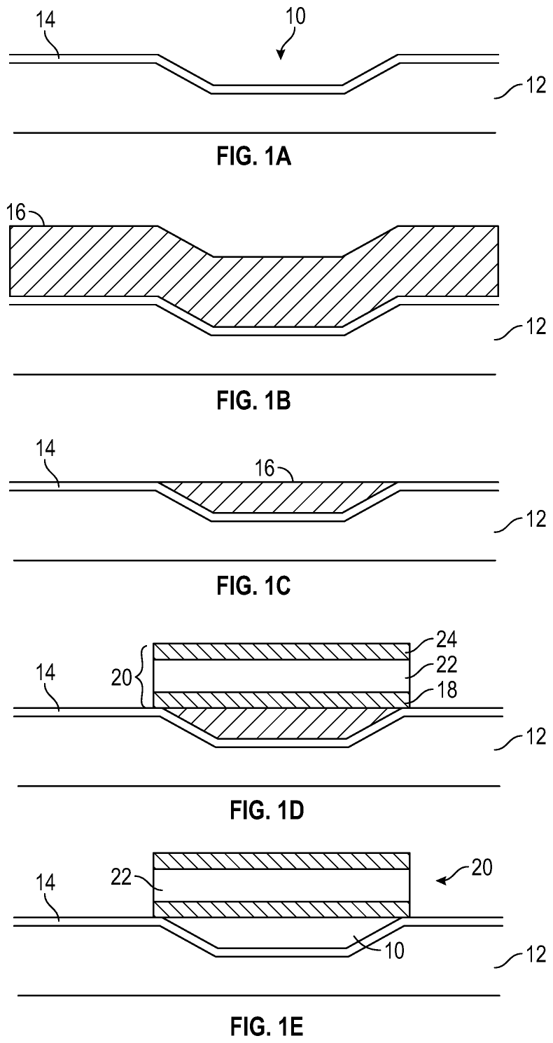

FIG. 2 shows a prior art process for growing a piezoelectric material on a first substrate to be used in a method for BAR device fabrication;

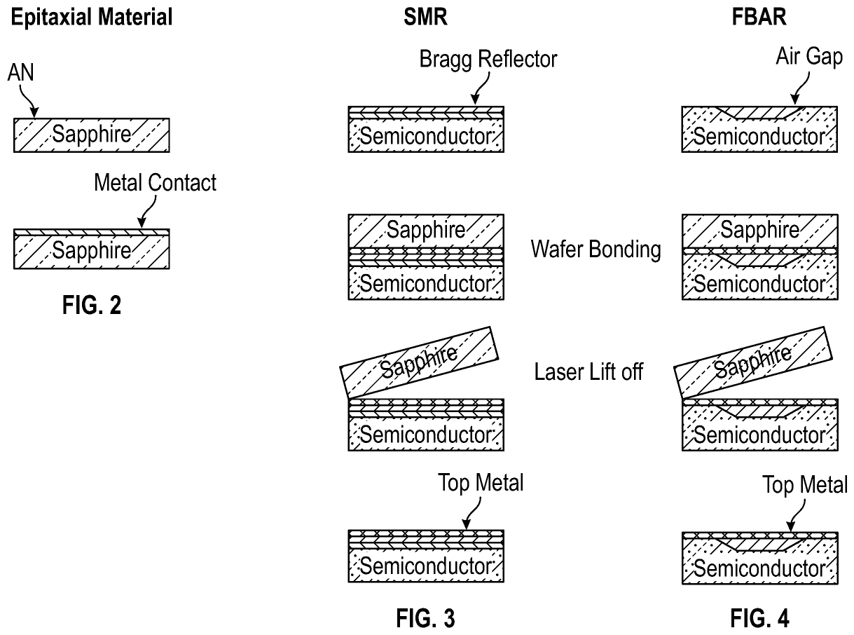

FIG. 3 shows a prior tart process for BAR device fabrication using an epitaxial transfer method for SMR fabrication;

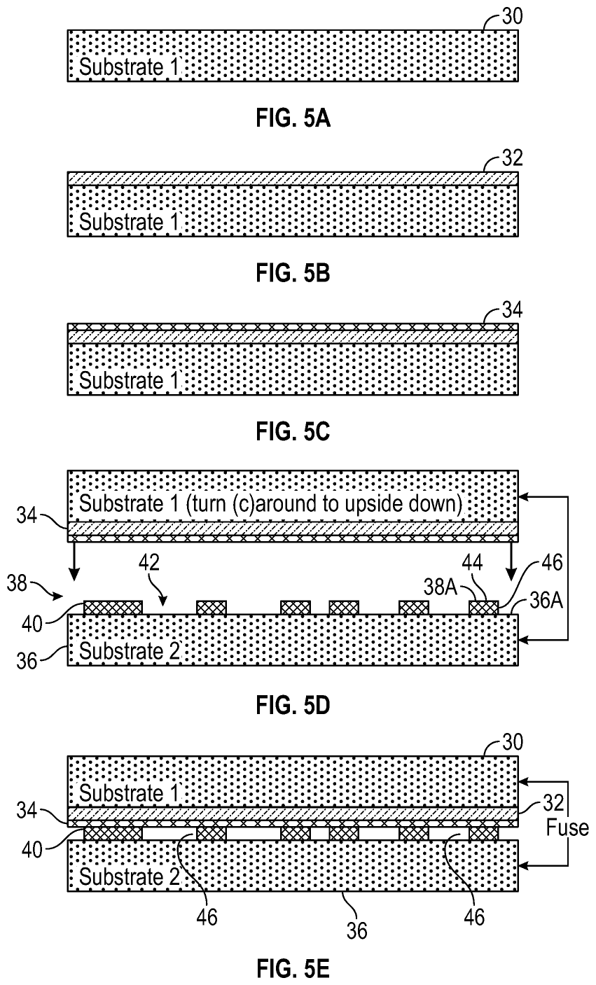

FIG. 4 shows a prior art process for BAR device fabrication using an epitaxial transfer method for FBAR fabrication;

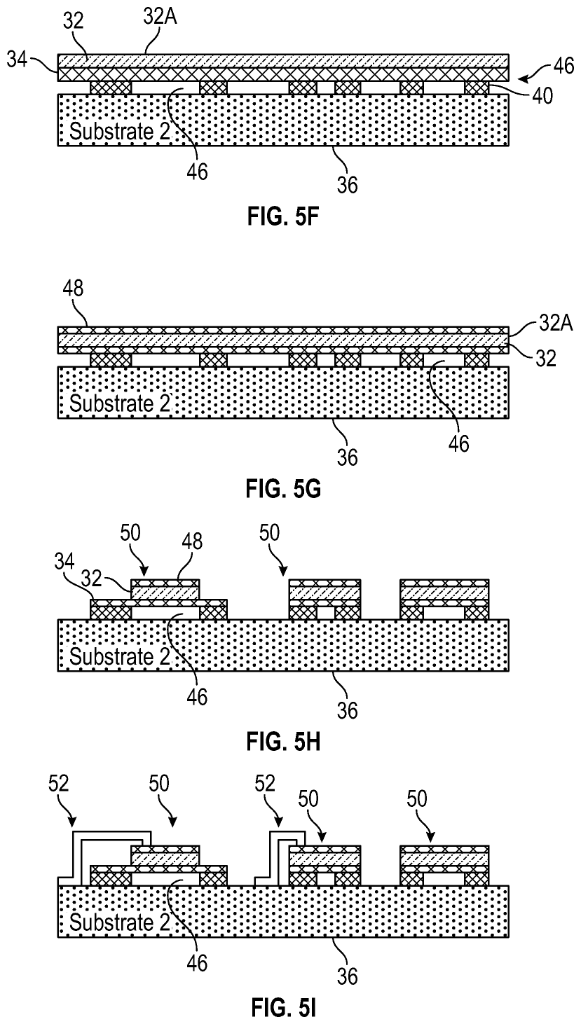

FIGS. 5A-5I show cross-sectional views of an exemplary process of forming a BAW resonator in accordance with one aspect of the current application;

FIGS. 6A-6I show cross-sectional views of an exemplary process of forming a BAW resonator in accordance with one aspect of the current application; and

FIGS. 7A-7B show cross-sectional views of an exemplary process of forming a BAW resonator package in accordance with one aspect of the current application.

### DESCRIPTION OF THE APPLICATION

The description set forth below in connection with the appended drawings is intended as a description of presently preferred embodiments of the disclosure and is not intended to represent the only forms in which the present disclosure may be constructed and/or utilized. The description sets forth the functions and the sequence of steps for constructing and operating the disclosure in connection with the illustrated embodiments. It is to be understood, however, that the same or equivalent functions and sequences may be accomplished by different embodiments that are also intended to be encompassed within the spirit and scope of this disclosure.

The current embodiment involves a novel cavity formation and its manufacturing process that may simplify the cavity formation underneath the film BAR (FBAR) structure, and may eliminate the need of substrate trench etching, subsequent planarization processes, micro-via formation, sacrificial layer and planarized support layer deposition and subsequent removal, and large area planar wafer bonding process over the prior arts. The new and novel cavity structure may be formed by separating the “metal-piezoelectric layer-metal” layer into two steps, and by flip-chip and transport the piezoelectric thin film onto pre-defined metal based and framed cavity structures with solder or eutectic alloy tips to “fuse” the piezoelectric thin films over the cavity regions. The present embodiment may simplify and eliminate any substrate trench etching and silica glass filling and planarization, micro trench and via formation and sacrificial/support layer deposition and removal, and thin film transfer through a large area planar wafer bonding processes which is inheritably a low yield process due to the wafer flatness variation and any voids or air pockets formation in between the two bonded substrates.

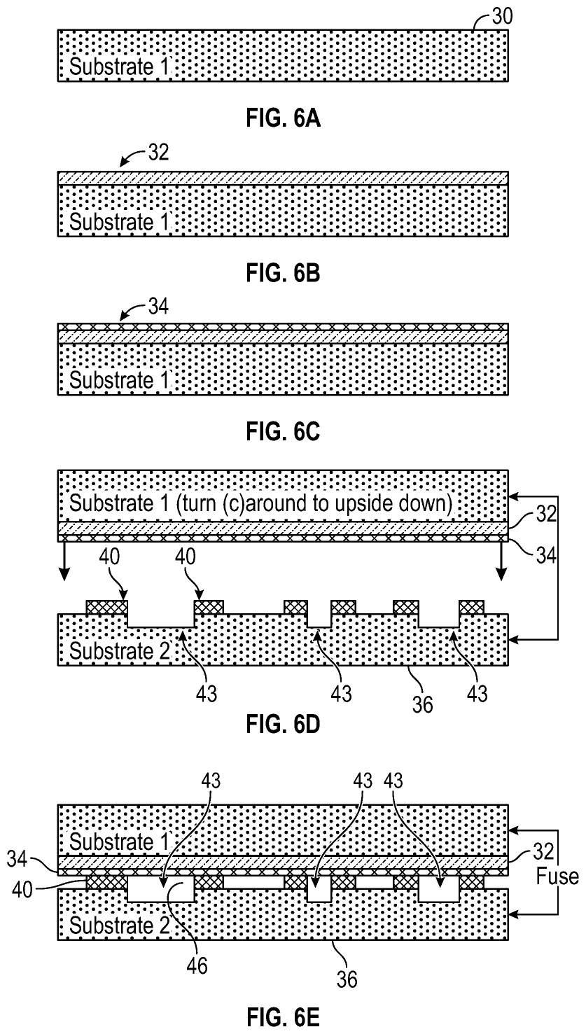

Referring to FIGS. 5A-5J, a process for cavity formation and manufacturing process for a Film Bulk Acoustic Resonator (FBAR) structure may be shown. A substrate 30 may be provided. The substrate 30 may be a conventional silicon wafer of the type utilized in integrated circuit fabrication. A piezoelectric film 32 may be formed directly on the substrate 30. The piezoelectric film 32 may be formed by (1) plasma sputtering deposited polycrystalline AlN on silicon or silicon oxide, (2) epitaxial single crystalline AlN on lattice match substrate such as Sapphire or similar processes. In this embodiment, a bottom metal layer (e.g., Molybdenum) may not be required initially. Thus, under the current embodiment, the piezoelectric film 32 quality may be better controlled and may stay consistent as it is either being deposited as polycrystalline on Si/SiOx substrate or epitaxial single crystalline grown on sapphire substrate. This is in comparison to prior art of Mo—AlN—Mo deposition which the AlN layer is subsequently deposited onto the underneath metal Mo layer surface. This may cause the AlN quality to be less optimized when it is deposited onto a metal surface instead of a Silicon/SiOx or single crystal Sapphire/GaN substrate surfaces.

As may be seen in FIG. 5C, a metal layer 34 may be applied to a top surface 32A of the piezoelectric film 32. In accordance with one embodiment, the metal layer 34 may be molybdenum. Molybdenum is a silvery-white metal that is ductile and may be highly resistant to corrosion. Molybdenum may have one of the highest melting points of all pure elements.

A second substrate 36 may be provided. The substrate 36 may be a conventional silicon wafer of the type utilized in integrated circuit fabrication. A metal pattern 38 may be formed on a top surface 36A of the substrate 36. The metal pattern 38 may be a plurality of metal post/pillars 40. The area between the metal post/pillars 40 may form a cavity pattern 42 on the substrate 36. The cavity pattern 42 may typically be non-regular shapes with dimensions in the range of one to several hundred microns in size. The metal pattern 38 and cavity pattern 42 may be created by photo lithographically patterned metal films, posts, walls, wells or the like. Solder tips 44 may be formed on a top surface 438A of the metal pattern 38.

As may be shown in FIGS. 5D-5E, wafer bonding may be performed between the structure on the substrate 30 and the structure formed on the substrate 36. Wafer bonding may be performed such that the metal layer 34 and the solder tips 44 on the metal post/pillars 40 may be coupled together. The bonding may be done by temperature and pressure using a bonding agent. The bonding agent may be a metallic eutectic or a dielectric layer. Au—Ge, Pd—In and glass frit may be some examples of such bonding agents. The above listing is given as an example and should not be seen in a limiting manner. Other bonding agents may be used without departing from the spirit and scope of the present invention.

The wafer bonding performed between the metal layer 34 and the solder tips 44 on the metal post/pillars 40 may form a plurality of cavity areas 46. Once the cavity areas 46 are formed, the substrate 30 may be removed to from the combined structure 46 as may be seen in FIG. 5F. The substrate 30 may be removed mechanically, chemically or a combination of both.

After the substrate 30 has been removed, a metal layer 48 may be formed on an exposed bottom surface 32A of the piezoelectric film 32. In accordance with one embodiment, the metal layer 48 may be a molybdenum metal layer. After the application of the metal layer 48, sections of the metal layer 48 and the piezoelectric film 32 may be removed to form one or more BAW cavity devices 50 as shown in FIG. 5H. As shown in the present embodiment, the metal layer 48 and the piezoelectric film 32 may be etched and removed either down to the substrate 36. In this configuration, the piezoelectric BAW cavity structure 50 is a rectangular cube in shape and the metal layer 34 may be exposed on the side surfaces of the piezoelectric BAW cavity structure 50. The metal layer 48 and the piezoelectric film 32 may be etched and removed so that that portions of the metal layer 34 may be exposed, the piezoelectric BAW cavity structure 50 in this configuration may be a tiered structure where the metal layer 34 may be exposed and parallel to the substrate 36.

As may be shown in FIG. 5I, interconnections 52 may be formed. The interconnections 52 may be formed between the piezoelectric BAW cavity structure 50 and wire traces formed within the substrate 36.

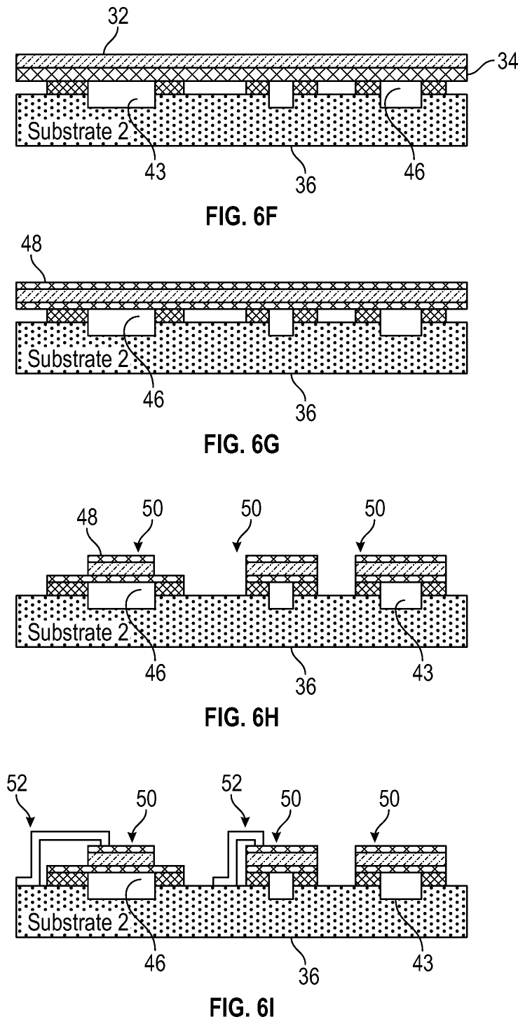

Referring to FIG. 6A-6I, another embodiment of a process for cavity formation and manufacturing process for a Film Bulk Acoustic Resonator (FBAR) structure may be shown. In this embodiment, the substrate 30 may be provided. The substrate 30 may be a conventional silicon wafer of the type utilized in integrated circuit fabrication. A piezoelectric film 32 may be formed directly on the substrate 30. The piezoelectric film 32 may be formed by (1) plasma sputtering deposited polycrystalline AlN on silicon or silicon oxide, (2) epitaxial single crystalline AlN on lattice match substrate such as Sapphire or by other similar processes. In this embodiment, a bottom metal layer (e.g., Molybdenum) may not be required initially. Thus, under the current embodiment, the piezoelectric film 32 quality may be better controlled and stay consistent because it is either deposited as polycrystalline on Si/SiOx substrate or epitaxial single crystalline grown on sapphire substrate. This is in comparison to the prior art of Mo—AlN—Mo deposition which the AlN layer is subsequently deposited onto the underneath metal Mo layer surface. This may cause the AlN quality to be less optimized when it is deposited onto a metal surface instead of a Silicon/SiOx or single crystal Sapphire/GaN substrate surfaces.

As may be seen in FIG. 6C, a metal layer 34 may be applied to a top surface 32A of the piezoelectric film 32. In accordance with one embodiment, the metal layer 34 may be molybdenum. Molybdenum is a silvery-white metal that is ductile and may be highly resistant to corrosion. Molybdenum may have one of the highest melting points of all pure elements.

A second substrate 36 may be provided. The substrate 30 may be a conventional silicon wafer of the type utilized in integrated circuit fabrication. A metal pattern 38 may be formed on a top surface 30A of the substrate 30. The metal pattern 38 may be a plurality of metal post/pillars 40. The area between the metal post/pillars 40 may form a cavity pattern 42 on the second substrate 36. The cavity pattern 42 may typically be non-regular shapes with dimensions in the range of one to several hundred microns in size.

In the present embodiment, the cavity pattern 42 may have trenches 43 formed in a bottom area of the cavity pattern 42. The trenches 43 may be formed in order for the cavity area 46 to achieve certain height requirements. The cavity pattern 42 and trenches 43 may be accomplished by creating a metal-based mask with solder or eutectic alloy tips on top to define the cavity patterns 42, and etch the extended cavity depth (trenches 43) into the substrate 36. All these can be easily achieved by standard photolithography, metal deposition and patterning through evaporation, sputtering, plating, etching or any combination of the above processes. The cavity pattern 42 may typically be non-regular shapes with dimensions in the range of one to several hundred microns in size. Solder tips 44 may be formed on a top surface 38A of the metal pattern 38.

As may be shown in FIGS. 6D-6E, wafer bonding may be performed between the structure on the substrate 30 and the structure formed on the substrate 36. Wafer bonding may be performed such that the metal layer 34 and the solder tips 44 on the metal post/pillars 40 may be coupled together. The bonding may be done by temperature and pressure using a bonding agent that may be a metallic eutectic or a dielectric layer. Au—Ge, Pd—In and glass frit may be some examples of such bonding agents. The above listing is given as an example and should not be seen in a limiting manner. Other bonding agents may be used without departing from the spirit and scope of the present invention.

The wafer bonding performed between the metal layer 34 and the solder tips 44 on the metal post/pillars 40 may form a plurality of cavity areas 46. Once the cavity areas 46 is formed, the substrate 30 may be removed from the combined structure 46 as may be seen in FIG. 5F. The substrate 30 may be removed mechanically, chemically or a combination of both.

After the substrate 30 has been removed, a metal layer 48 may be formed on an exposed bottom surface 32A of the piezoelectric film 32. In accordance with one embodiment, the metal layer 48 may be a molybdenum metal layer. After the application of the metal layer 48, sections of the metal layer 48 and the piezoelectric film 32 may be removed to form a plurality of piezoelectric BAW cavity structures 50 as may be seen in FIG. 6H. As shown in the present embodiment, the metal layer 48 and the piezoelectric film 32 may be etched and removed either down to the substrate 36 so that the piezoelectric BAW cavity structure 50 is a rectangular cube in shape. In this configuration, the metal layer 34 may be exposed on the side surfaces of the piezoelectric BAW cavity structure 50. The metal layer 48 and the piezoelectric film 32 may be etched and removed so that that portions of the metal layer 34 may be exposed and parallel to the substrate 36. In this configuration, the piezoelectric BAW cavity structure 50 may be a tiered structure.

As may be shown in FIG. 6I, interconnections 52 may be formed. The interconnections 52 may be formed between the piezoelectric BAW cavity structure 50 and wire traces formed within the substrate 36.

The piezoelectric BAW cavity structure 50 of FIGS. 5I and 6I may be electrically connected through interconnections 50 and other circuit elements such as thin film resisters, thin film capacitors, and inductors, with interconnects and pads to form a piezoelectric BAW package for use in different applications. The piezoelectric BAW package may be used for microwave filter and/or duplexer applications as well as other applications. While FIGS. 5I and 6I may show a front mounting of bond wire version, piezoelectric BAW cavity structure 50 may also have a flip chip version.

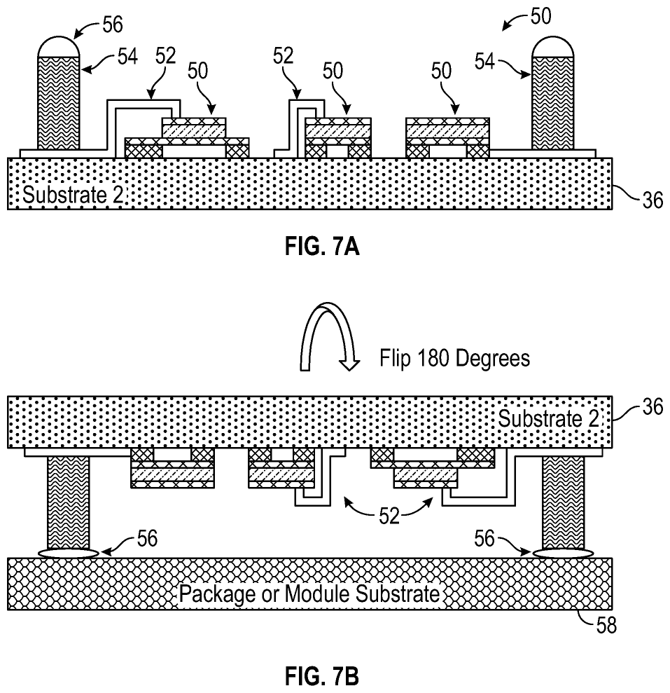

Referring to FIG. 7A-7B, a method of forming a flip chip piezoelectric BAW package 60 using the piezoelectric BAW cavity structure 50 may be shown. Metal pillars 54 may be formed on the substrate 36. The metal pillars 54 may be formed around one or more of the piezoelectric BAW cavity structures 50 formed on the substrate 50. In accordance with one embodiment, the metal pillars 54 may be formed of copper. However, this is shown as an example and should not be seen in a limiting manner. Solder 56 may be placed on a top surface of each metal pillar 54. The substrate 50 with the BAW cavity structures 50 and the metal pillars 54 may then be flipped 180° and placed on a package substrate 58 bonding the metal pillars 54 to the package substrate 58 to form the flip chip piezoelectric BAW package 60. The bonding may be done by temperature and pressure using a bonding agent. The bonding agent may be a metallic eutectic or a dielectric layer. Au—Ge, Pd—In and glass frit may be some examples of such bonding agents. The above listing is given as an example and should not be seen in a limiting manner. Other bonding agents may be used without departing from the spirit and scope of the present invention.

The present method may differ from all prior art through the use of partial piezoelectric film (metal-piezoelectric film) versus (metal-piezoelectric-metal film) transport from initial substrate to a pre-patterned cavity structured of metal films, posts, walls, or wells with solder or eutectic alloy tips and by fusing of the flipped piezoelectric film to the underneath patterned substrate. The present method may further differ from all prior art since after fusing the piezoelectric film to the metal-based cavity structures and the initial substrate is removed from the back, a second metal layer may be deposited on the exposed piezoelectric film to form the full and complete piezoelectric film structure.

While embodiments of the disclosure have been described in terms of various specific embodiments, those skilled in the art will recognize that the embodiments of the disclosure may be practiced with modifications within the spirit and scope of the claims

What is claimed is:

1. A method for forming a Bulk Acoustic Wave (BAW) structure comprising:
forming a piezoelectric material on a first substrate;
applying a first metal layer on a top surface of the piezoelectric material;
forming a metal pattern on a second substrate, the metal pattern forming a cavity pattern between raised areas of the metal pattern;
attaching the first metal layer to a top area of the metal pattern forming a plurality of cavity areas;
removing the first substrate; and
applying a second metal layer on a bottom surface of the piezoelectric material.

2. The method of claim 1, comprising removing portions of the second metal layer and the piezoelectric material to form a plurality of BAW structures, each of the plurality of BAW structures having one of the plurality of cavity areas.

3. The method of claim 1, comprising removing portions of the second metal layer and the piezoelectric material down to the first substrate to form a plurality of BAW structures, wherein the first metal layer is exposed on side surfaces of at least one of the plurality of BAW structures, each of the plurality of BAW structures having one of the plurality of cavity areas.

4. The method of claim 1, comprising removing portions of the second metal layer and the piezoelectric material forming a plurality of BAW structures, wherein the first metal layer is exposed and parallel to the first substrate.

5. The method of claim 2, comprising etching into the first substrate in the cavity pattern deepening at least one of the plurality of cavity areas.

6. The method of claim 2, comprising forming interconnects on at least one of the plurality of BAW structures.

7. The method of claim 1, wherein the first metal layer is formed of Molybdenum (Mo).

8. The method of claim 1, wherein the second metal layer is formed of Molybdenum (Mo).

9. The method of claim 1, wherein the piezoelectric material is a piezoelectric AlN layer.

10. The method of claim 2, comprising:
forming a plurality of mounting pillars on the first substrate; and
flip chip mounting the first substrate with the plurality of mounting pillars on to a third substrate.

11. The method of claim 1, wherein forming the metal pattern comprises forming a plurality of metal post/pillars, an area between the metal post/pillars forming the cavity pattern.

12. A method for forming a Bulk Acoustic Wave (BAW) structure comprising:
forming a piezoelectric material on a first substrate;
applying a first metal layer on a top surface of the piezoelectric material;
forming a metal pattern on a second substrate, the metal pattern forming a cavity pattern between raised areas of the metal pattern;
attaching the first metal layer to a top area of the metal pattern forming a plurality of cavity areas;
removing the first substrate;
applying a second metal layer on a bottom surface of the piezoelectric material;
removing portions of the second metal layer and the piezoelectric material to form a plurality of BAW structures, each of the plurality of BAW structures having one of the plurality of cavity areas; and
forming interconnects on at least one of the plurality of BAW structures.

13. The method of claim 12, comprising removing portions of the second metal layer and the piezoelectric material down to the first substrate to form a plurality of BAW structures, wherein the first metal layer is exposed on side surfaces of at least one of the plurality of BAW structures, each of the plurality of BAW structures having one of the plurality of cavity areas.

14. The method of claim 12, comprising removing portions of the second metal layer and the piezoelectric material forming a plurality of BAW structures, wherein the first metal layer is exposed and parallel to the first substrate on at least one of the plurality of BAW structures.

15. The method of claim 12, comprising etching into the first substrate in the cavity pattern deepening at least one of the plurality of cavity areas.

16. The method of claim 12, comprising:
forming a plurality of mounting pillars on the first substrate; and
flip chip mounting the first substrate with the plurality of mounting pillars on to a third substrate.

17. A method for forming a Bulk Acoustic Wave (BAW) structure comprising:
forming a piezoelectric material on a first substrate;
applying a first metal layer on a top surface of the piezoelectric material;
forming a metal pattern on a second substrate, the metal pattern forming a cavity pattern between raised areas of the metal pattern;
etching into the first substrate in the cavity pattern deepening at least one of the plurality of cavity areas;
attaching the first metal layer to a top area of the metal pattern forming a plurality of cavity areas;
removing the first substrate;
applying a second metal layer on a bottom surface of the piezoelectric material;
removing portions of the second metal layer and the piezoelectric material to form a plurality of BAW structures, each of the plurality of BAW structures having one of the plurality of cavity areas;
forming interconnects on at least one of the plurality of BAW structures;
forming a plurality of mounting pillars on the first substrate; and
flip chip mounting the first substrate with the plurality of mounting pillars on to a third substrate.

18. The method of claim 17, comprising removing portions of the second metal layer and the piezoelectric material down to the first substrate to form a plurality of BAW structures, wherein the first metal layer is exposed on side surfaces of at least one of the plurality of BAW structures, each of the plurality of BAW structures having one of the plurality of cavity areas.

19. The method of claim 17, comprising removing portions of the second metal layer and the piezoelectric material forming a plurality of BAW structures, wherein the first metal layer is exposed and parallel to the first substrate on at least one of the plurality of BAW structures.

20. The method of claim 17, wherein the first metal layer and the second metal layer are formed of Molybdenum (Mo).
